(19) United States
(12) Patent Application Publication
(10) Pub. No.: US 2026/0308420 A1
(43) Pub. Date: Oct. 8, 2026

(54) RESIN COMPOSITION, ADHESIVE MEMBER, AND ELECTRONIC APPARATUS INCLUDING THE ADHESIVE MEMBER

(71) Applicant: Samsung Display Co., Ltd., Yongin-si (KR)

(72) Inventor: Naoto INOUE, Kanagawa (JP)

(73) Assignee: Samsung Display Co., Ltd., Yongin-si (KR)

(21) Appl. No.: 19/555,236

(22) Filed: Mar. 3, 2026

(30) Foreign Application Priority Data
Apr. 7, 2025 (JP) 2025-062974

(51) Int. Cl. C09J 7/30; C09J 4/00; C09J 7/10

(52) U.S. Cl. CPC C09J 7/30; C09J 4/00; C09J 7/10; C09J 2203/326; C09J 2301/414; C09J 2301/416; C09J 2400/146

(57) ABSTRACT

A resin composition includes a urethane acrylate compound, a monomer including one polymerizable unsaturated group per molecule, and a photopolymerization initiator. The urethane acrylate compound is synthesized from reactants including a first polyfunctional alcohol including the structure of chemical formula 1 below, a second polyfunctional alcohol different from the first polyfunctional alcohol, a polyfunctional isocyanate-based compound, a compound including at least one (meth)acryloyl group and at least one hydroxyl group per molecule, and a mono-alcohol. The content of the structure of chemical formula 1 in the urethane acrylate compound is 20 wt % or more and 60 wt % or less based on the total weight of the urethane acrylate compound, and the content of the monomer is 50 wt % or more and 95 wt % or less based on the total weight of the resin composition.

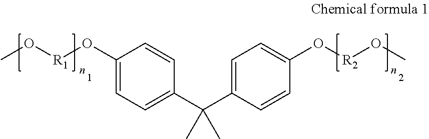

### CROSS-REFERENCE TO RELATED APPLICATION(S)

This application claims priority to and the benefit of Japanese Patent Application No. 2025-062974, filed on Apr. 7, 2025, the disclosure of which is incorporated by reference herein in its entirety.

### BACKGROUND

### 1. Field

The present disclosure relates to a resin composition, an adhesive member formed of the resin composition, and an electronic apparatus including the adhesive member.

### 2. Description of Related Art

Various display devices used in multimedia devices such as televisions, mobile phones, tablet computers, navigation systems, and game consoles are being developed. A display device includes various components that constitute the display device, and an adhesive member is disposed between these components. The adhesive member is formed using a resin composition. The adhesive member included in the display device is required to have properties that stably bond the components of the display device and do not degrade display quality.

### SUMMARY

The present disclosure provides a resin composition with high adhesive properties and excellent lightfastness after being cured, an adhesive member formed from the resin composition, and an electronic apparatus including the adhesive member.

Embodiments of the present disclosure provide a resin composition including a urethane acrylate compound including a structure of chemical formula 1 below, a monomer including one polymerizable unsaturated group per molecule, and a photopolymerization initiator. The urethane acrylate compound is synthesized from reactants including a first polyfunctional alcohol including the structure of chemical formula 1 below, a second polyfunctional alcohol different from the first polyfunctional alcohol, a polyfunctional isocyanate-based compound, a compound including at least one (meth)acryloyl group and at least one hydroxyl group per molecule, and a mono-alcohol. A content of the structure of chemical formula 1 in the urethane acrylate compound is 20 wt % or more and 60 wt % or less based on a total weight of the urethane acrylate compound, and a content of the monomer is 50 wt % or more and 95 wt % or less based on a total weight of the resin composition.

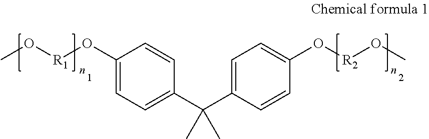

In chemical formula 1, each of R₁ and R₂ is independently a substituted or unsubstituted alkylene group having 1 or more to 4 or less carbon atoms, and each of n₁ and n₂ is independently an integer of 1 or more and 6 or less.

A 180° peel strength with respect to a glass substrate, measured at 25° C. after photocuring under a condition where a cumulative UV dose is less than 2000 mJ/cm² in the atmosphere, is 2000 gf/25 mm or more to 5000 gf/25 mm or less.

The polymerizable unsaturated group in the monomer is an acrylate group.

The monomer includes at least one of 4-hydroxybutyl acrylate, tetrahydrofurfuryl acrylate, isobornyl acrylate, isodecyl acrylate, lauryl acrylate (C12), 2-ethylhexyl acrylate, and 2-{2-[(2-ethylhexyl)oxy]ethoxy}ethyl acrylate.

The urethane acrylate compound has a weight-average molecular weight of 5,000 or more to 10,000 or less, and the urethane acrylate compound has a number-average molecular weight of 2,000 or more to 8,000 or less.

A yellowness index right after photocuring or a yellowness index after a 48-hour exposure to a xenon arc lamp under a condition of 0.4 W/50° C. is 1 or less.

The second polyfunctional alcohol includes at least one of 2,2-bis(hydroxymethyl)butyric acid, ethylene glycol, propylene glycol, butylene glycol, butylethylpropanediol, polyethylene glycol, and polypropylene glycol.

The polyfunctional isocyanate-based compound includes at least one of 1,3-bis(isocyanatomethyl)cyclohexane and isophorone diisocyanate.

The mono-alcohol includes an unsaturated mono-alcohol and a saturated mono-alcohol, the unsaturated mono-alcohol includes at least one of hydroxy dicyclopentadiene, 3-cyclohexene-1-methanol, and trans-2-hexen-1-ol, and the saturated mono-alcohol includes at least one of methanol, ethanol, n-propanol, isopropanol, and n-butanol.

The photopolymerization initiator includes bis(2,4,6-trimethylbenzoyl)phenyl phosphine oxide.

The resin composition further includes an ultraviolet light (UV) absorber.

The resin composition is provided by an inkjet printing method or a dispensing method.

Embodiments of the present disclosure provide an adhesive member including a polymer obtained from a resin composition. The resin composition includes a urethane acrylate compound including a structure of chemical formula 1 below, a monomer including one polymerizable unsaturated group per molecule, and a photopolymerization initiator. The urethane acrylate compound is synthesized from reactants including a first polyfunctional alcohol including the structure of chemical formula 1 below, a second polyfunctional alcohol different from the first polyfunctional alcohol, a polyfunctional isocyanate-based compound, a compound including at least one (meth)acryloyl group and at least one hydroxyl group per molecule, and a mono-alcohol. A content of the structure of chemical formula 1 in the urethane acrylate compound is 20 wt % or more and 60 wt % or less based on a total weight of the urethane acrylate compound, and a content of the monomer is 50 wt % or more and 95 wt % or less based on a total weight of the resin composition.

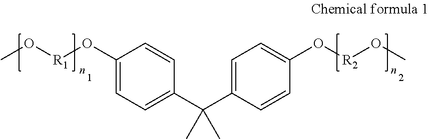

In chemical formula 1, each of R₁ and R₂ is independently a substituted or unsubstituted alkylene group having 1 or more to 4 or less carbon atoms, and each of n₁ and n₂ is independently an integer of 1 or more and 6 or less.

A 180° peel strength of the adhesive member with respect to a glass substrate measured at 25° C. is in a range of 2000 gf/25 mm or more to 5000 gf/25 mm or less.

The adhesive member has a thickness in a range of 50 m or more and 300 m or less.

Embodiments of the present disclosure provide an electronic apparatus including a display device providing an image. The display device includes at least one adhesive member including a polymer obtained from a resin composition. The resin composition includes a urethane acrylate compound including a structure of chemical formula 1 below, a monomer including one polymerizable unsaturated group per molecule, and a photopolymerization initiator. The urethane acrylate compound is synthesized from reactants including a first polyfunctional alcohol including the structure of chemical formula 1 below, a second polyfunctional alcohol different from the first polyfunctional alcohol, a polyfunctional isocyanate-based compound, a compound including at least one (meth)acryloyl group and at least one hydroxyl group per molecule, and a mono-alcohol. A content of the structure of chemical formula 1 in the urethane acrylate compound is 20 wt % or more and 60 wt % or less based on a total weight of the urethane acrylate compound, and a content of the monomer is 50 wt % or more and 95 wt % or less based on a total weight of the resin composition.

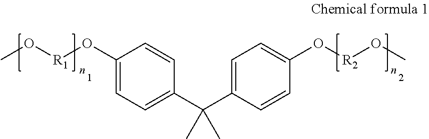

In chemical formula 1, each of R₁ and R₂ is independently a substituted or unsubstituted alkylene group having 1 or more to 4 or less carbon atoms, and each of n₁ and n₂ is independently an integer of 1 or more and 6 or less.

A 180° peel strength of the adhesive member with respect to a glass substrate, which is measured at 25° C., is in a range of 2000 gf/25 mm or more to 5000 gf/25 mm or less.

The display device includes a display module and a window, and the adhesive member is between the display module and the window.

The window includes a base layer and a printed layer between the adhesive member and the base layer, and the adhesive member is formed by irradiating the resin composition on one surface of the display module or on one surface of the window with light through the printed layer.

The display device includes a display module, a processor, a memory, and a power module.

According to the above, the resin composition has high adhesive properties and excellent lightfastness after being cured.

According to the above, the adhesive member exhibit high adhesive properties and excellent lightfastness.

According to the above, the electronic apparatus includes the polymer obtained from the resin composition and exhibits excellent reliability and superior display quality.

### BRIEF DESCRIPTION OF DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a block diagram of an electronic apparatus according to an embodiment of the present disclosure;

FIG. 2 is a schematic view of electronic apparatuses according to embodiments of the present disclosure;

FIG. 3 is a perspective view of an electronic apparatus according to an embodiment of the present disclosure;

FIG. 4 is an exploded perspective view of a display device according to an embodiment of the present disclosure;

FIG. 5 is a cross-sectional view taken along line I-I′ of FIG. 4;

FIG. 6 is a cross-sectional view of a portion of a display device according to an embodiment of the present disclosure;

FIG. 7A is a view showing a method of manufacturing an adhesive member according to an embodiment of the present disclosure;

FIG. 7B is a view showing a method of manufacturing an adhesive member according to an embodiment of the present disclosure;

FIG. 7C is a view showing a method of manufacturing an adhesive member according to an embodiment of the present disclosure;

FIG. 7D is a view showing a method of manufacturing an adhesive member according to an embodiment of the present disclosure;

FIG. 8A is a view showing a method of manufacturing an adhesive member according to an embodiment of the present disclosure;

FIG. 8B is a view showing a method of manufacturing an adhesive member according to an embodiment of the present disclosure;

FIG. 8C is a view showing a method of manufacturing an adhesive member according to an embodiment of the present disclosure;

FIG. 9 is a cross-sectional view of a display device according to an embodiment of the present disclosure; and

FIG. 10 is a cross-sectional view of a display device according to an embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and should be construed to include all modifications, equivalents, or replacements included in the spirit and scope of the present disclosure.

In the present disclosure, it will be understood that when an element (or area, layer, or portion) is referred to as being “on”, “connected to” or “coupled to” another element (or area, layer, or portion), it can be directly on, connected or coupled to the other element (or area, layer, or portion), or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that although the terms first, second, etc. may be used herein to describe various elements, these elements should not be limited by these terms. These terms are only used to distinguish one element from another element. Thus, a first element discussed below could be termed a second element without departing from the teachings of the present disclosure. As an example, without departing from the scope of the present disclosure, a first component, a first part, a first region, a first layer, and a first portion could be referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another element or feature as shown in the figures.

It will be further understood that the terms “include” and/or “including”, when used in this specification, specify the presence of stated features, integers, steps, operations, elements, components, and/or groups, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a resin composition, an adhesive member, and an electronic apparatus including the adhesive member according embodiments of the present disclosure will be described with reference to accompanying drawings. A display device according to an embodiment of the present disclosure is applied to various electronic apparatuses. The electronic apparatus includes the display device and further includes a module or device with other additional functions in addition to the display device.

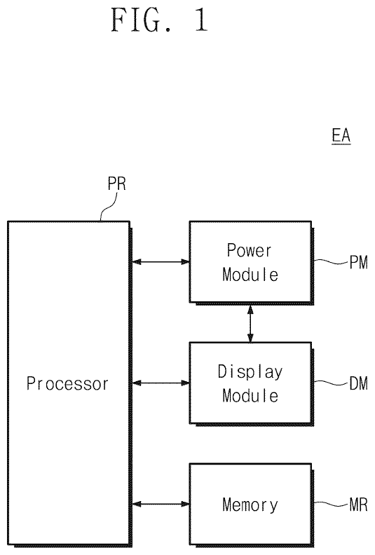

FIG. 1 is a block diagram of the electronic apparatus according to an embodiment of the present disclosure. Referring to FIG. 1, the electronic apparatus EA may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), and a controller.

The memory MR may store data information required for the operation of the processor PR or the display module DM. When the processor PR executes an application stored in the memory MR, an image data signal and/or an input control signal may be transmitted to the display module DM, and the display module DM may process the received signals to output image information through a display screen.

The power module PM may include a power supply module and a power conversion module that converts power supplied by the power supply module, such as a power adapter or a battery device, to generate power required for the operation of the electronic apparatus EA.

At least one of the components of the electronic apparatus EA may be included in the display device according to embodiments described above. In addition, among individual modules that are functionally included within a single module, some may be included in the display device while others may be provided separately from the display device. As an example, the display device may include the display module DM, and the processor PR, the memory MR, and the power module PM may be provided as separate devices within the electronic apparatus EA, rather than being included in the display device.

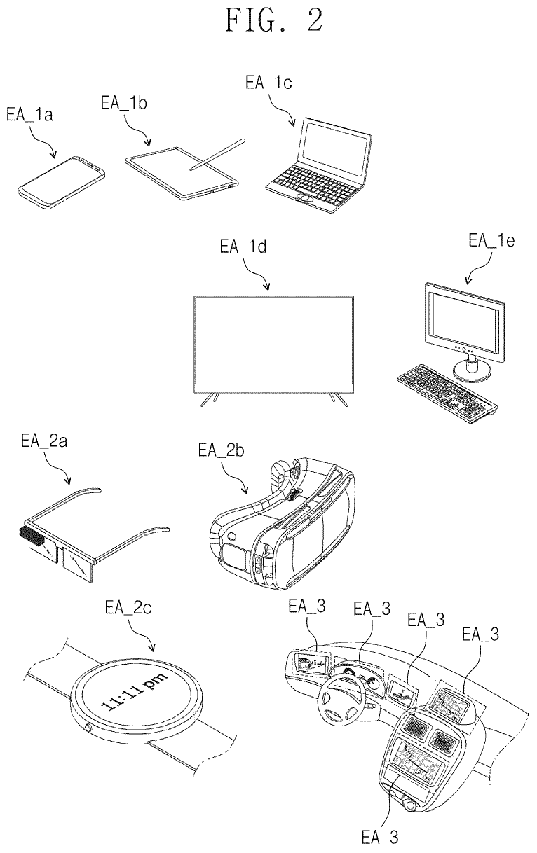

FIG. 2 is a schematic view of electronic apparatuses according to embodiments of the present disclosure. Referring to FIG. 2, various electronic apparatuses to which the display device according to embodiments is applied may include not only an electronic apparatus to display images, such as a smartphone EA_1a, a tablet PC EA_1b, a laptop computer EA_1c, a television EA_1d, a desktop monitor EA_1e, etc., but also a wearable electronic apparatus including a display module, such as smart glasses EA_2a, a head-mounted display EA_2b, a smartwatch EA_2c, etc., and an in-vehicle electronic apparatus EA_3 including a display module, such as an instrument panel, a center fascia, a dashboard-mounted center information display (CID), a room mirror display, etc.

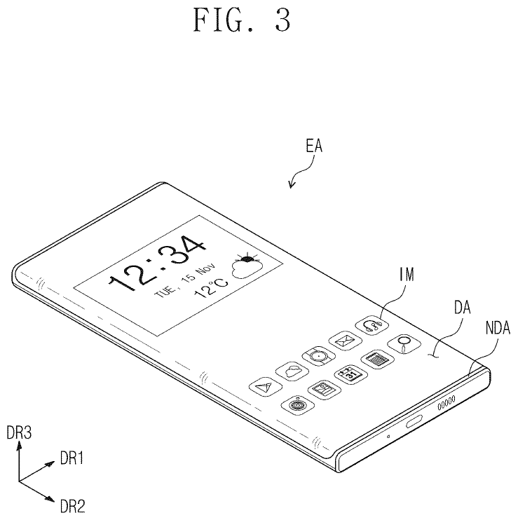

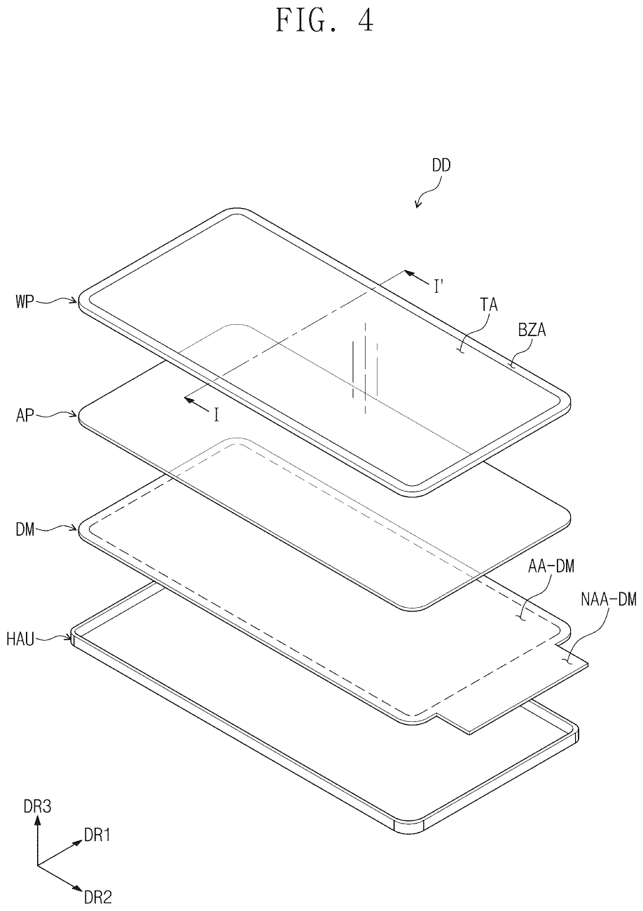

FIG. 3 is a perspective view of an electronic apparatus according to an embodiment of the present disclosure. FIG. 4 is an exploded perspective view of a display device according to an embodiment of the present disclosure.

The electronic apparatus EA shown in FIG. 3 may be activated in response to electrical signals. FIG. 3 shows a smartphone as a representative example of the electronic apparatus EA.

The electronic apparatus EA may display an image IM through a display area DA. The display area DA may include a plane defined by a first directional axis DR1 and a second directional axis DR2. The display area DA may include a curved surface bent from at least one side of the plane defined by the first directional axis DR1 and the second directional axis DR2. The electronic apparatus EA shown in FIG. 3 may include two curved surfaces respectively bent from two sides of the plane defined by the first directional axis DR1 and the second directional axis DR2, but it should not be limited thereto or thereby. As an example, the display area DA may include only the plane defined by the first directional axis DR1 and the second directional axis DR2, or the display area DA may further include two or more curved surfaces, e.g., four curved surfaces respectively bent from four sides of the plane defined by the first directional axis DR1 and the second directional axis DR2.

The electronic apparatus EA of the present disclosure may be flexible. The term “flexible” used herein refers to the property of being able to be bent from a structure that is completely bent to a structure that is bent at the scale of a few nanometers. For example, the electronic apparatus EA may be a foldable display device. According to an embodiment, the electronic apparatus EA may be rigid.

A non-display area NDA may be defined adjacent to the display area DA. The non-display area NDA may surround the display area DA. Accordingly, the display area DA may have a shape that is substantially defined by the non-display area NDA, but this is merely an example. The non-display area NDA may be defined adjacent to only one side of the display area DA or may be omitted. According to an embodiment, the display area DA may be provided in various shapes, and it should not be particularly limited.

FIG. 3 and the following drawings show first, second, and third directional axes DR1, DR2, and DR3, and directions indicated by the first, second, and third directional axes DR1, DR2, and DR3 may be relative to each other and may be changed in other directions. In addition, the directions indicated by the first, second, and third directional axes DR1, DR2, and DR3 may be referred to as first, second, and third directions, respectively, and the first, second, and third directions may be assigned with the same reference numerals as those of the first, second, and third directional axes DR1, DR2, and DR3. In the following descriptions, the first directional axis DR1 may be substantially perpendicular to the second directional axis DR2, and the third directional axis DR3 may be a normal line direction with respect to the plane defined by the first directional axis DR1 and the second directional axis DR2.

A thickness direction of the electronic apparatus EA may be substantially parallel to the third directional axis DR3 that is the normal line direction of the plane defined by the first directional axis DR1 and the second directional axis DR2. In the present embodiment, a front surface (or an upper surface, an upper portion surface, or an upper side) and a rear surface (or a lower surface, a lower portion surface, or a lower side) of each member of the electronic apparatus EA may be defined with respect to the third directional axis DR3. In addition, a direction to which the third directional axis DR3 extends may be substantially parallel to the thickness direction, the front surface (or the upper surface, the upper portion surface, or the upper side) may indicate a surface (or a direction) adjacent to a surface through which the image IM is displayed, and the rear surface (or the lower surface, the lower portion surface, or the lower side) may indicate a surface (or a direction) spaced apart from the surface through which the image IM is displayed. In the present disclosure, the term “plane” means a surface substantially parallel to the plane defined by the first directional axis DR1 and the second directional axis DR2, and the term “cross-section” means a surface perpendicular to the plane defined by the first directional axis DR1 and the second directional axis DR2 and substantially parallel to the thickness direction DR3.

FIG. 4 is an exploded perspective view of the display device according to an embodiment of the present disclosure. The display device DD shown in FIG. 4 may be included in the electronic apparatus EA shown in FIG. 3.

Referring to FIG. 4, the display device DD may include a display module DM, a window WP disposed on the display module DM, and an adhesive member AP disposed between the display module DM and the window WP. In addition, the display device DD may further include a housing HAU accommodating the display module DM.

In the display device DD shown in FIG. 4, the window WP and the housing HAU may be coupled to each other to provide an exterior of the display device DD. The housing HAU may be disposed under the display module DM. The housing HAU may include a material with a relatively high rigidity. As an example, the housing HAU may include a plurality of frames and/or plates formed of a glass, plastic, or metal material. The housing HAU may provide an accommodation space. The display module DM may be accommodated in the accommodation space and may be protected from external impacts.

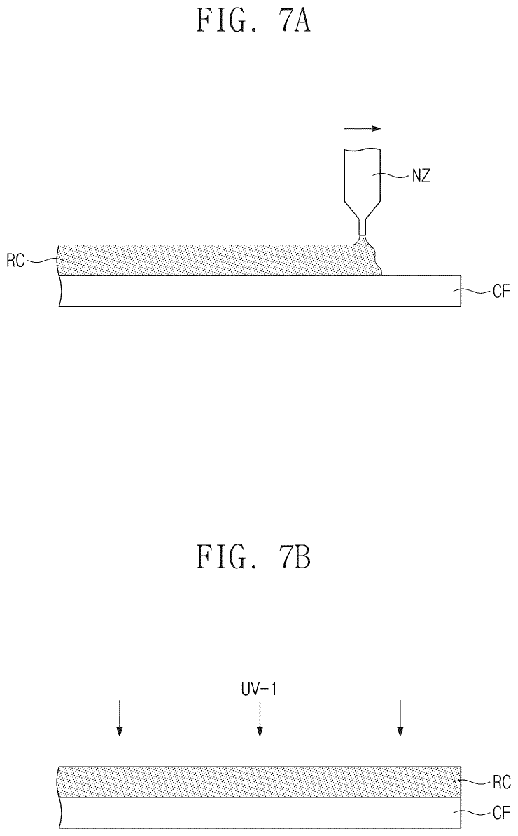

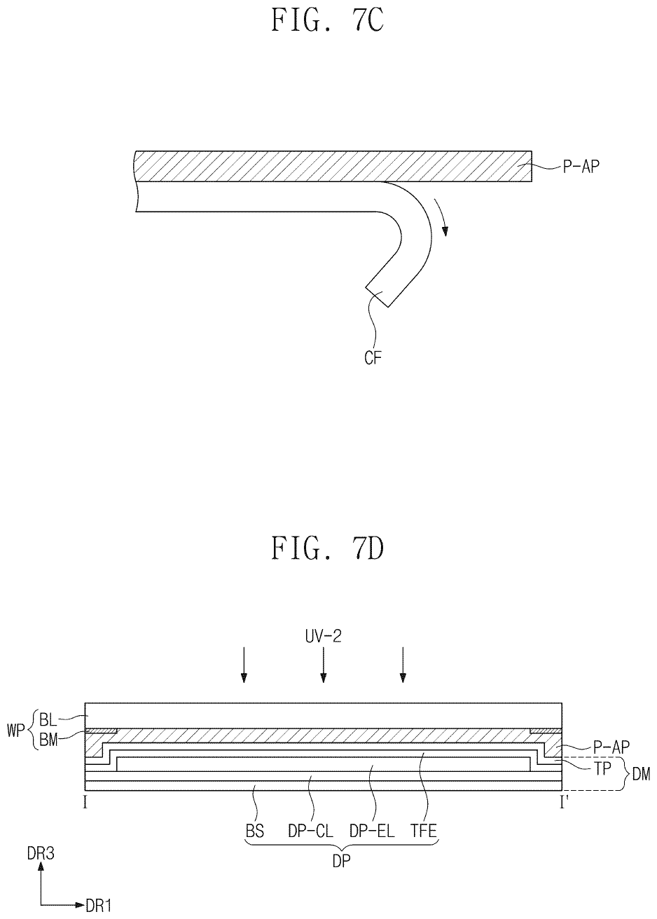

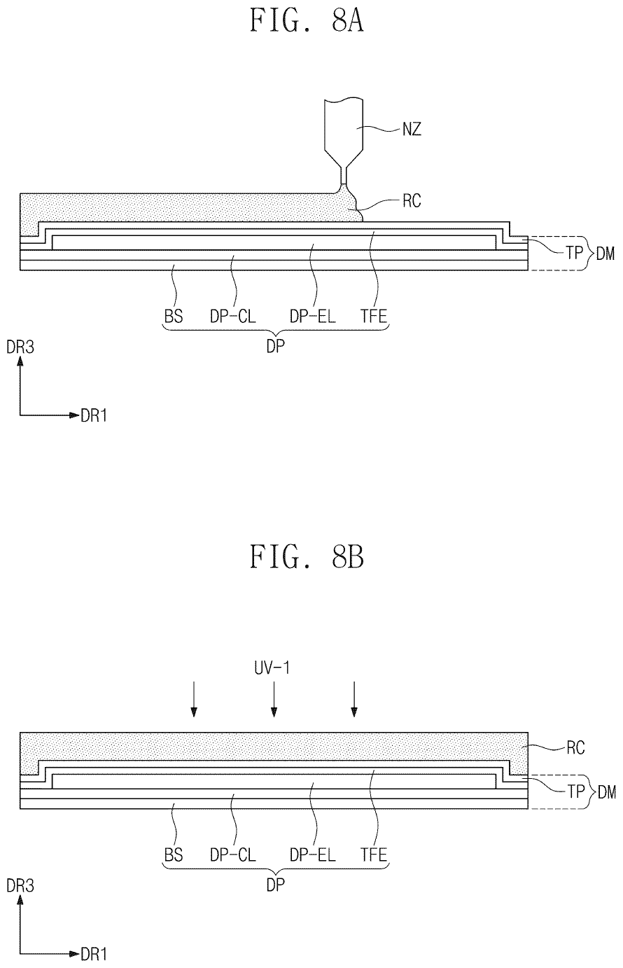

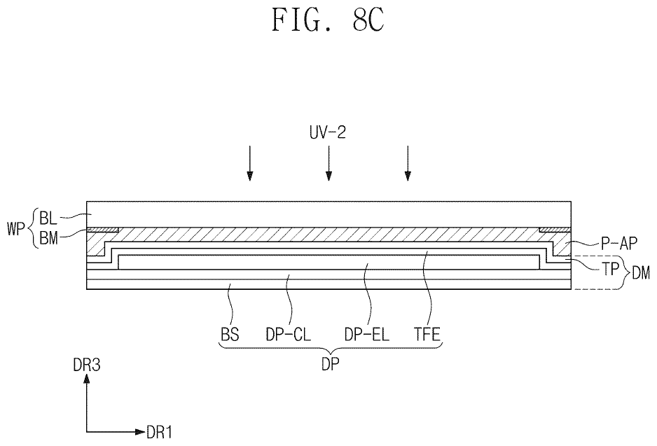

In an embodiment, the adhesive member AP may include a polymer obtained from a resin composition RC (refer to FIGS. 7A and 8A). The adhesive member AP may be formed by photocuring the resin composition RC (refer to FIGS. 7B and 8B). The display module DM and the window WP may be attached to each other by the adhesive member AP. The adhesive member AP may be formed from the resin composition RC (refer to FIGS. 7A and 8A) and may exhibit excellent adhesion reliability. Further, in an embodiment, the adhesive member AP may be prevented from discoloring by an external light, such as an ultraviolet (UV) light.

The window WP may include a transmissive area TA and a bezel area BZA. The transmissive area TA may overlap at least a portion of an active area AA-DM of the display module DM. The transmissive area TA may be an optically transparent area. The image IM (refer to FIG. 3) may be provided to a user through the transmissive area TA.

The bezel area BZA may be an area having a relatively lower transmittance than that of the transmissive area TA. The bezel area BZA may define a shape of the transmissive area TA. The bezel area BZA may be disposed adjacent to the transmissive area TA and may surround the transmissive area TA.

The bezel area BZA may have a color. The bezel area BZA may cover a peripheral area NAA-DM of the display module DM to prevent the peripheral area NAA-DM from being viewed from the outside, but this is merely an example. The bezel area BZA may be disposed adjacent to only one side of the transmissive area TA or at least a portion thereof may be omitted.

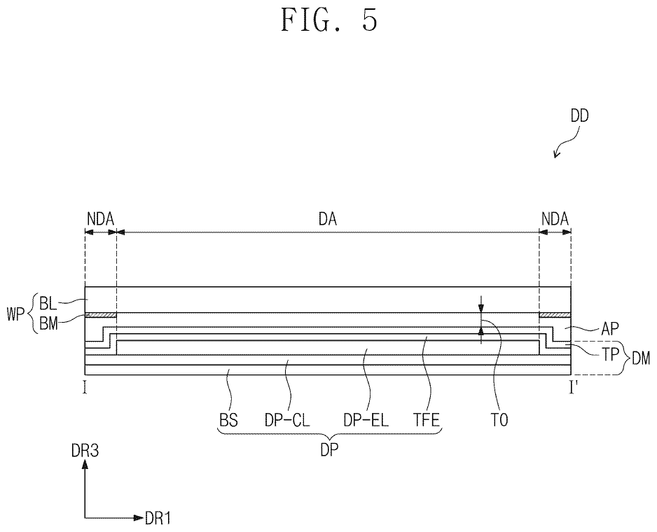

FIG. 5 is a cross-sectional view taken along a line I-I′ of FIG. 4. FIG. 5 is a cross-sectional view of the display device including the display module DM, the adhesive member AP, and the window WP of FIG. 4.

Referring to FIG. 5, the display module DM may include a display panel DP and an input sensing unit TP disposed on the display panel DP. The display panel DP may have a configuration that substantially generates images. The display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The adhesive member AP may be disposed between the display module DM and the window WP. When the display module DM includes the display panel DP and the input sensing unit TP, the adhesive member AP may be disposed between the input sensing unit TP and the window WP.

The display panel DP shown in FIG. 5 is merely an example, and the structure of the display panel DP should not be limited thereto or thereby. As an example, the display panel DP may include a liquid crystal display element, and in this case, the encapsulation layer TFE may be omitted.

The base substrate BS may provide a base surface on which the circuit layer DP-CL is disposed. The base substrate BS may be a flexible substrate that is bendable, foldable, or rollable. The base substrate BS may be a glass substrate, a metal substrate, or a polymer substrate. However, the embodiment should not be limited thereto or thereby, and the base substrate BS may be an inorganic layer, an organic layer, or a composite material layer.

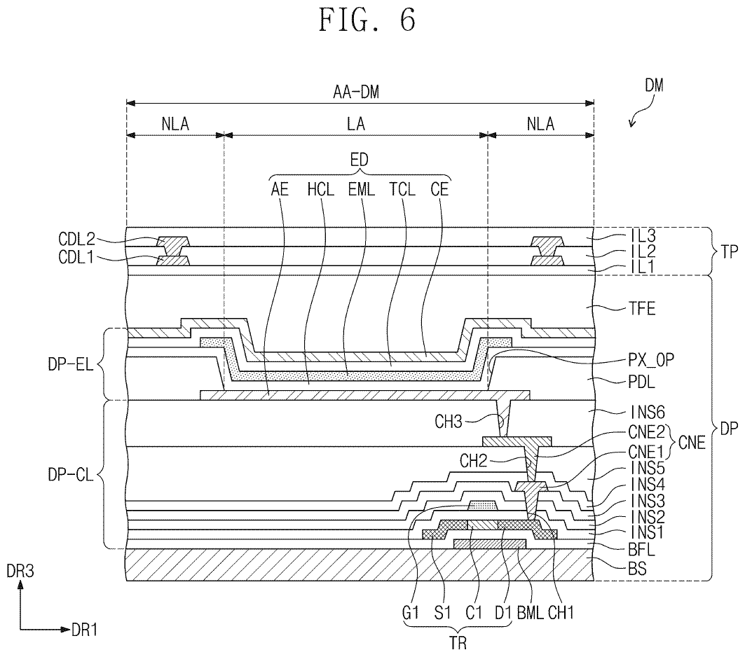

The circuit layer DP-CL may include an insulating layer, a semiconductor pattern, a conductive pattern, and a signal line. As an example, the circuit layer DP-CL may include a switching transistor and a driving transistor to drive a light emitting element ED (refer to FIG. 6) of the display element layer DP-EL.

The display element layer DP-EL may include the light emitting element ED (refer to FIG. 6) emitting light. For example, the light emitting element ED (refer to FIG. 6) may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-EL. The encapsulation layer TFE may protect the display element layer DP-EL from moisture, oxygen, and/or a foreign substance such as dust particles. The encapsulation layer TFE may include at least one inorganic layer. As an example, the encapsulation layer TFE may include an inorganic layer, an organic layer, and an inorganic layer, which are sequentially stacked.

The input sensing unit TP may be disposed on the display panel DP. As an example, the input sensing unit TP may be disposed directly on the encapsulation layer TFE of the display panel DP. Alternatively, an adhesive layer may be disposed between the input sensing unit TP and the display panel DP.

In the following descriptions, when a component is described as being directly disposed on/provided on another component, it means that no third component is disposed/provided between the two components. In other words, when a component is ‘directly disposed on/provided on’ another component, it means that the one component and the other component are ‘in contact’.

The input sensing unit TP may sense an external input, may convert the external input to an input signal, and may provide the input signal to the display panel DP. As an example, the input sensing unit TP of the display device DD may be a touch sensing unit sensing a touch event. The input sensing unit TP may sense a direct touch of a user, an indirect touch of the user, a direct touch of an object, or an indirect touch of the object.

The input sensing unit TP may sense at least one of a position of the touch event applied from the outside of the input sensing unit TP and an intensity (pressure) of the touch event applied from the outside of the input sensing unit TP. The input sensing unit TP may have various structures or may include various materials, and it should not be particularly limited. As an example, the input sensing unit TP may sense the external input in a capacitive manner. The display panel DP may receive the input signal from the input sensing unit TP and may generate an image corresponding to the input signal.

The window WP may include a base layer BL and a printed layer BM. Although not shown in figures, the window WP may further include at least one functional layer (not shown) disposed on the base layer BL. As an example, the functional layer (not shown) may be a hard coating layer or an anti-fingerprint coating layer, but it should not be limited thereto or thereby.

The base layer BL may be a glass substrate. Alternatively, the base layer BL may be a plastic substrate. As an example, the base layer BL may include polyimide, polyacrylate, polymethylmethacrylate, polycarbonate, polyethylenenaphthalate, polyvinylidene chloride, polyvinylidene difluoride, polystyrene, ethylene vinyl alcohol copolymer, or combinations thereof.

The printed layer BM may be disposed on one surface of the base layer BL. The printed layer BM may be disposed on a lower surface of the base layer BL, which is adjacent to the display module DM. The printed layer BM may be disposed at an edge of the base layer BL. The printed layer BM may be an ink printed layer. In addition, the printed layer BM may be a layer formed of a pigment or dye. The printed layer BM may be formed to include a light-absorbing material or may be formed to include a black pigment or a black dye. However, this is merely an example, and the present disclosure should not be limited thereto or thereby. In the window WP, the bezel area BZA (refer to FIG. 4) may be a portion on which the printed layer BM is provided.

The adhesive member AP may have a thickness T0 of 50 μm or more and 300 μm or less. For example, the adhesive member AP may have the thickness T0 of 50 μm or more and 250 μm or less. However, this is merely an example, and the thickness T0 of the adhesive member AP should not be limited thereto or thereby.

FIG. 6 is a cross-sectional view illustrating the display module DM of FIG. 5 in more detail. The structure of the display module DM shown in FIG. 6 is merely an example, and the present disclosure should not be limited thereto or thereby.

The base substrate BS may have a single-layer or multi-layer structure. For instance, the base substrate BS may include a first synthetic resin layer, an inorganic layer having a single-layer or multi-layer structure, and a second synthetic resin layer disposed on the inorganic layer having the single-layer or multi-layer structure. Each of the first and second synthetic resin layers may include a polyimide-based resin. In addition, each of the first and second synthetic resin layers may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In the present disclosure, the term “X-based resin”, as used herein, refers to the resin that includes a functional group of X.

The display panel DP may include a transistor TR and the light emitting element ED. The transistor TR and the light emitting element ED may be disposed on the base substrate BS. As an example, one transistor TR is shown in FIG. 6, but the display panel DP may include a plurality of transistors and at least one capacitor to drive the light emitting element ED.

The circuit element layer DP-CL may be disposed on the base substrate BS. The circuit element layer DP-CL may include a light shielding electrode BML, the transistor TR, a connection electrode CNE, and a plurality of insulating layers BFL and INS1 to INS6. The insulating layers BFL and INS1 to INS6 may include a buffer layer BFL and first, second, third, fourth, fifth, and sixth insulating layers INS1, INS2, INS3, INS4, INS5, and INS6. However, the cross-section of the circuit element layer DP-CL shown in FIG. 6 is merely an example, and the stack structure of the circuit element layer DP-CL may be changed in various ways depending on the configuration of the display panel DP and the processes of the circuit element layer DP-CL.

The light shielding electrode BML may be disposed on the base substrate BS. The light shielding electrode BML may overlap the transistor TR. The light shielding electrode BML may block light from entering the transistor TR from a lower side of the display panel DP to protect the transistor TR. The light shielding electrode BML may include a conductive material. When a voltage is applied to the light shielding electrode BML, a threshold voltage of the transistor TR disposed on the light shielding electrode BML may be maintained, but the present disclosure should not be limited thereto or thereby. According to an embodiment, the light shielding electrode BML may be a floating electrode. According to an embodiment, the light shielding electrode BML may be omitted.

The buffer layer BFL may be disposed on the base substrate BS to cover the light shielding electrode BML. The buffer layer BFL may be an inorganic layer. The buffer layer BFL may improve an adhesive force between the semiconductor pattern disposed on the buffer layer BFL and the base substrate BS or between the conductive pattern and the base substrate BS.

The transistor TR may include a source S1, a channel C1, a drain D1, and a gate G1. The source S1, the channel C1, and the drain D1 of the transistor TR may be formed from the semiconductor pattern. The semiconductor pattern of the transistor TR may include polysilicon, amorphous silicon, or a metal oxide and should not be particularly limited as long as a material for the transistor TR has a semiconductor property.

The semiconductor pattern may include a plurality of areas distinguished from each other depending on a level of conductivity. A portion of the semiconductor pattern which is doped with a dopant or a portion of the semiconductor pattern where a metal oxide is reduced may have a relatively high conductivity and may serve as the source S1 and the drain D1 of the transistor TR. The portion of the semiconductor pattern which has a relatively high conductivity may correspond to the source S1 and the drain D1 of the transistor TR. A non-doped portion, a portion doped at low-concentration, or a portion where the metal oxide is not reduced, which is provided with a relatively low conductivity, may correspond to the channel C1 (or an active) of the transistor TR.

The first insulating layer INS1 may be disposed on the buffer layer BFL and may cover the semiconductor pattern of the transistor TR. The gate G1 of the transistor TR may be disposed on the first insulating layer INS1. The gate G1 may overlap with the channel C1 of the transistor TR. The gate G1 may be used as a mask in a process of doping the semiconductor pattern of the transistor TR.

The second insulating layer INS2 may be disposed on the first insulating layer INS1 and may cover the gate G1. The third insulating layer INS3 may be disposed on the second insulating layer INS2.

The connection electrode CNE may include a first connection electrode CNE1 and a second connection electrode CNE2 to electrically connect the transistor TR and the light emitting element ED. However, the connection electrode CNE that electrically connects the transistor TR and the light emitting element ED should not be limited thereto or thereby. According to an embodiment, one of the first and second connection electrodes CNE1 and CNE2 may be omitted, or the connection electrode CNE may further include an additional connection electrode.

The first connection electrode CNE1 may be disposed on the third insulating layer INS3. The first connection electrode CNE1 may be connected to the drain D1 via a first contact hole CH1 defined through the first to third insulating layers INS1 to INS3. The fourth insulating layer INS4 may be disposed on the third insulating layer INS3 and may cover the first connection electrode CNE1. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 via a second contact hole CH2 defined through the fourth and fifth insulating layers INS4 and INS5. The sixth insulating layer INS6 may be disposed on the fifth insulating layer INS5 and may cover the second connection electrode CNE2.

Each of the first to sixth insulating layers INS1 to INS6 may include an inorganic layer or an organic layer. As an example, the inorganic layer may include at least one of aluminum oxide, titanium oxide, silicon oxide, silicon oxynitride, zirconium oxide, and hafnium oxide. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

The display element layer DP-EL may include a pixel definition layer PDL and the light emitting element ED. The light emitting element ED may include a first electrode AE, a hole control layer HCL, a light emitting layer EML, an electron control layer TCL, and a second electrode CE.

The first electrode AE may be disposed on the sixth insulating layer INS6. The first electrode AE may be connected to the second connection electrode CNE2 via a third contact hole CH3 defined through the sixth insulating layer INS6. The first electrode AE may be connected to the drain D1 of the transistor TR through the first and second connection electrodes CNE1 and CNE2.

The first electrode AE may be formed of a metal material, a metal alloy, or a conductive compound. The first electrode AE may be an anode or a cathode. In addition, the first electrode AE may be a pixel electrode. The first electrode AE may be a transmissive electrode, a transflective electrode, or a reflective electrode. The first electrode AE may include at least one selected from, a compound of two or more selected from, a mixture of two or more selected from, or an oxide of Ag, Mg, Cu, Al, Pt, Pd, Au, Ni, Nd, Ir, Cr, Li, Ca, LiF, Mo, Ti, W, In, Sn, and Zn.

When the first electrode AE is the transmissive electrode, the first electrode AE may include a transparent metal oxide, e.g., indium tin oxide (ITO), indium zinc oxide (IZO), zinc oxide (ZnO), indium tin zinc oxide (ITZO), or the like. When the first electrode AE is the transflective or reflective electrode, the first electrode AE may include Ag, Mg, Cu, Al, Pt, Pd, Au, Ni, Nd, Ir, Cr, Li, Ca, LiF/Ca (a stack structure of LiF and Ca), LiF/Al (a stack structure of LiF and Al), Mo, Ti, W, a compound thereof, or a mixture thereof, e.g., a mixture of Ag and Mg. According to an embodiment, the first electrode AE may have a multi-layer structure of a reflective layer or a transflective layer, which is formed of the above-mentioned material, and a transparent conductive layer formed of indium tin oxide (ITO), indium zinc oxide (IZO), zinc oxide (ZnO), indium tin zinc oxide (ITZO), or the like. As an example, the first electrode AE may have a three-layer structure of ITO/Ag/ITO, but it should not be limited thereto or thereby. According to an embodiment, the first electrode AE may include the metal material, a combination of two or more of the metal materials, or an oxide of the metal materials.

The pixel definition layer PDL may be disposed on the sixth insulating layer INS6. The pixel definition layer PDL may be formed of a polymer resin. For example, the pixel definition layer PDL may be formed to include a polyacrylate-based resin or a polyimide-based resin. In addition, the pixel definition layer PDL may be formed to include an inorganic material in addition to the polymer resin. The pixel definition layer PDL may be formed to include a light absorbing material or may be formed to include a black pigment or a black dye. The pixel definition layer PDL formed to include the black pigment or the black dye may form a black pixel definition layer. When the pixel definition layer PDL is formed, a carbon black may be used as the black pigment or black dye, but the present disclosure should not be limited thereto or thereby.

In addition, the pixel definition layer PDL may be formed of an inorganic material. For example, the pixel definition layer (PDL) may be formed of inorganic materials such as silicon nitride (SiNx), silicon oxide (SiOx), and silicon oxynitride (SiOxNy).

A light emitting opening PX_OP may be defined through the pixel definition layer PDL to expose a portion of the first electrode AE. The portion of the first electrode AE exposed through the light emitting opening PX_OP may correspond to a light emitting area LA.

The active area AA-DM of the display module DM may include the light emitting area LA and a non-light-emitting area NLA. An area in which the pixel definition layer PDL is disposed may correspond to the non-light-emitting area NLA. The non-light-emitting area NLA may surround the light emitting area LA in the display area DA.

The hole control layer HCL may be disposed on the first electrode AE and the pixel definition layer PDL. The hole control layer HCL may be provided as a common layer that overlaps with the light emitting area LA and the non-light-emitting area NLA. The hole control layer HCL may include at least one of a hole transport layer, a hole injection layer, and an electron block layer. The hole control layer HCL may include a known hole injection material and/or a known hole transport material.

The light emitting layer EML may be disposed on the hole control layer HCL. The light emitting layer EML may be disposed in an area corresponding to the light emitting opening PX_OP. However, the present disclosure should not be limited thereto or thereby, and the light emitting layer EML may be provided as a common layer. The light emitting layer EML may include an organic light emitting material and/or an inorganic light emitting material. The light emitting layer EML may emit a light having one of red, green, and blue colors. As an example, the light emitting layer EML may emit a blue light.

The electron control layer TCL may be disposed on the light emitting layer EML. The electron control layer TCL may be provided as a common layer that overlaps with the light emitting area LA and the non-light-emitting area NLA. The electron control layer TCL may include at least one of an electron transport layer, an electron injection layer, and a hole block layer. The electron control layer TCL may include a known electron injection material and/or a known electron transport material.

The second electrode CE may be disposed on the electron control layer TCL. The second electrode CE may be provided as a common layer that overlaps with the light emitting area LA and the non-light-emitting area NLA.

The second electrode CE may be a common electrode. The second electrode CE may be a cathode or an anode. As an example, when the first electrode AE is the anode, the second electrode CE may be the cathode, and when the first electrode AE is the cathode, the second electrode CE may be the anode.

The second electrode CE may be a transmissive electrode, a transflective electrode, or a reflective electrode. In the case where the second electrode CE is the transmissive electrode, the second electrode CE may include a transparent metal oxide, e.g., indium tin oxide (ITO), indium zinc oxide (IZO), zinc oxide (ZnO), indium tin zinc oxide (ITZO), etc.

In the case where the second electrode CE is the transflective electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof, e.g., AgMg, AgYb, or MgYb. In addition, the second electrode CE may have a multi-layer structure of a reflective layer or a transflective layer, which is formed of the above-mentioned material, and a transparent conductive layer formed of indium tin oxide (ITO), indium zinc oxide (IZO), zinc oxide (ZnO), or indium tin zinc oxide (ITZO). As an example, the second electrode CE may include the above-mentioned metal material, a combination of two or more metal materials selected from the above-mentioned metal materials, or an oxide of the above-mentioned metal materials.

The encapsulation layer TFE may be disposed on the second electrode CE to cover the light emitting element ED. The encapsulation layer TFE may include a plurality of thin layers. As an example, the encapsulation layer TFE may include inorganic layers disposed on the second electrode CE and an organic layer disposed between the inorganic layers. The inorganic layers may protect the light emitting element ED from moisture and oxygen, and the organic layer may protect the light emitting element ED from a foreign substance such as dust particles.

The input sensing unit TP may include a first sensing insulating layer IL1, a second sensing insulating layer IL2, and a third sensing insulating layer IL3. The input sensing unit TP may include at least one conductive layer disposed on the sensing insulating layers. The input sensing unit TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may be in contact with the encapsulation layer TFE, but the present disclosure should not be limited thereto or thereby. According to an embodiment, the first sensing insulating layer IL1 may be omitted, and in this case, the first conductive layer CDL1 may be in contact with the encapsulation layer TFE.

The first conductive layer CDL1 may be disposed on the first sensing insulating layer IL1. The first conductive layer CDL1 may include a plurality of first conductive patterns. The first conductive patterns may be disposed on the first sensing insulating layer IL1. The second sensing insulating layer IL2 may be disposed on the first sensing insulating layer IL1 to cover at least a portion of the first conductive layer CDL1.

The second conductive layer CDL2 may be disposed on the second sensing insulating layer IL2. The second conductive layer CDL2 may include a plurality of second conductive patterns. The second conductive patterns may be disposed on the second sensing insulating layer IL2. The second conductive patterns may be connected to the first conductive patterns via a contact hole defined through the second sensing insulating layer IL2.

Each of the first conductive patterns of the first conductive layer CDL1 and the second conductive patterns of the second conductive layer CDL2 may be disposed corresponding to the non-light-emitting area NLA. Each of the first conductive patterns of the first conductive layer CDL1 and the second conductive patterns of the second conductive layer CDL2 may correspond to a mesh pattern.

The third sensing insulating layer IL3 may be disposed on the second sensing insulating layer IL2 and may cover the second conductive layer CDL2. The second sensing insulating layer IL2 and the third sensing insulating layer IL3 may include an inorganic insulating layer or an organic insulating layer.

Each of the first conductive layer CDL1 and the second conductive layer CDL2 may have a single-layer structure or a multi-layer structure of layers stacked in the third direction DR3. The first and second conductive layers CDL1 and CDL2 having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer (e.g., PEDOT), a metal nanowire, and a graphene.

The conductive layers CDL1 and CDL2 having the multi-layer structure may include a plurality of metal layers. The metal layers may have a three-layer structure of titanium (Ti)/aluminum (Al)/titanium (Ti). The first and second conductive layers CDL1 and CDL2 having the multi-layer structure may include at least one metal layer and at least one transparent conductive layer.

FIGS. 7A to 7D are views schematically showing a method of manufacturing the adhesive member AP from the resin composition RC according to an embodiment of the present disclosure. As an example, the manufacturing method of the adhesive member AP may include providing the resin composition RC on a substrate CF, providing a first light UV-1 to the resin composition RC to form a preliminary adhesive member P-AP, and providing a second light UV-2 to the preliminary adhesive member P-AP to form the adhesive member AP. In the following descriptions with reference to FIGS. 7A to 7D, descriptions that are the same as those provided with reference to FIGS. 1 to 6 are omitted, and the description will focus on the differences.

Referring to FIG. 7A, the resin composition RC may be provided on the substrate CF. The resin composition RC may be provided on the substrate CF through a nozzle NZ. For example, the substrate CF on which the resin composition RC is provided may include polyethylene terephthalate (PET). The substrate CF may be a temporary substrate used to form the adhesive member AP (refer to FIGS. 4 and 5) from the resin composition RC and may not be particularly limited as long as the substrate CF is easily detachable after the resin composition RC is cured. One surface of the substrate CF on which the resin composition RC is provided may be release-treated.

In an embodiment, the resin composition RC may be provided by an inkjet printing method or a dispensing method. In an embodiment, the resin composition RC in a liquid state may be provided in a uniform amount and/or at a uniform speed. Although FIG. 7A illustrates the resin composition RC being provided through the nozzle NZ, devices to provide the resin composition RC should not be limited thereto or thereby.

According to an embodiment, the resin composition RC may include a urethane acrylate compound including a structure of chemical formula 1 below, a monomer including one polymerizable unsaturated group per molecule, and a photopolymerization initiator. The content of the monomer may be 50 wt % or more and 95 wt % or less based on the total weight of the resin composition. The urethane acrylate compound may be synthesized from reactants including a first polyfunctional alcohol including a structure of chemical formula 1 below, a second polyfunctional alcohol different from the first polyfunctional alcohol, a polyfunctional isocyanate-based compound, a compound including at least one (meth)acryloyl group and at least one hydroxyl group per molecule, and a mono-alcohol. The content of the structure of chemical formula 1 in the urethane acrylate compound may be 20 wt % or more and 60 wt % or less based on the total weight of the urethane acrylate compound.

In the present disclosure, the term “a (meth)acryloyl group” refers to an acryloyl or methacryloyl group, and “(meth)acryl” refers to acryl or methacryl.

In the present disclosure, all references to the structure of chemical formula 1 may mean chemical formula 1 below.

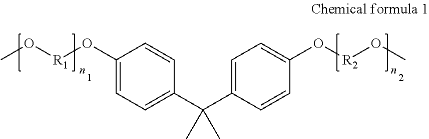

In chemical formula 1, R₁ and R₂ may each independently be a substituted or unsubstituted alkylene group having 1 or more and 4 or less carbon atoms. The alkylene group may include, for example, a methylene group, an ethylene group, a propylene group, a butylene group, a pentylene group, a hexylene group, and the like. The alkylene group may include linear, branched, and cyclic forms.

In an embodiment, R₁ and R₂ may be a branched propylene group. R₁ and R₂ may be the same or different.

In chemical formula 1, n₁ and n₂ may each independently be an integer from 1 to 6. n₁ and n₂ may be the same or different.

In one embodiment, the resin composition RC may have a viscosity of 20 mPa s or less as measured at 25° C. by JIS K2283. In an embodiment, the resin composition RC may have a viscosity of 5 mPa s or more and 20 mPa s or less as measured at 25° C. by JIS K2283. The resin composition RC, having a low viscosity, may be provided using an inkjet printing method or the like.

In an embodiment, the resin composition RC may exhibit a 180° peel strength of 2000 gf/25 mm or more and 6000 gf/25 mm or less with respect to a glass substrate as measured at 25° C. after being photocured under a condition in which a UV dose in the atmosphere is less than 2000 mJ/cm². The resin composition RC having a 180° peel strength of less than 2000 gf/25 mm with respect to the glass substrate after curing may not have sufficient adhesive strength to an adjacent component of the display device, for example, a display module and/or a window. The resin composition RC according to the present disclosure may have excellent adhesive strength after curing despite its low viscosity.

In an embodiment, the resin composition RC may have a yellowness index (YI) of 1 or less when measured immediately after UV curing. The measurement of the yellowness index immediately after the UV curing process may be performed to check discoloration or coloration of the adhesive member caused by the UV curing process. A yellowness index greater than 1 immediately after the UV curing process may indicate that the curing process has caused discoloration or coloration of the adhesive member.

In an embodiment, the resin composition RC may have a yellowness index of 1 or less after a 48-hour exposure under conditions of 0.4 W/50° C. using a xenon arc lamp after the photocuring process. This may be a lightfastness test conducted to check resistance to discoloration, fading, and the like of the adhesive member when exposed to sunlight or the like.

The yellowness index (YI) of 1 or less after exposure to sunlight may indicate that the adhesive member AP has high resistance to discoloration or fading when exposed to sunlight including UV rays, and thus, the adhesive member AP may have excellent lightfastness.

On the other hand, a yellowness index (YI) greater than 1 after exposure to sunlight may indicate that the adhesive member has low resistance to discoloration, fading, and the like when exposed to sunlight or the like. This may mean that discoloration and/or fading of the adhesive member may occur as exposure time to external light such as sunlight accumulates.

Hereinafter, the yellowness index measured after exposure to sunlight in the present disclosure refers to the yellowness index measured after using sunlight simulated by the xenon arc lamp. The simulation of sunlight using the xenon arc lamp may be performed, for example, using a Q-SUN xenon test chamber from Q-Lab.

Further, the yellowness index in the present disclosure refers to a value measured using a spectrophotometer (COH 7700, Nippon Denshoku Industries Co., Ltd.).

Accordingly, the resin composition RC may have excellent adhesion reliability and excellent lightfastness after curing. In addition, the adhesive member formed by curing the resin composition RC and the electronic apparatus including the adhesive member may also have excellent adhesion reliability and excellent lightfastness.

In an embodiment, the resin composition RC may include the monomer having one polymerizable unsaturated group per molecule. The content of the monomer may be 50 wt % or more and 95 wt % or less based on the total weight of the resin composition. The polymerizable unsaturated group in the monomer may be an acrylate group. The monomer may include at least one of 4-hydroxybutyl acrylate, tetrahydrofurfuryl acrylate, isobornyl acrylate, isodecyl acrylate, lauryl acrylate (C12), stearyl acrylate (C18), isostearyl acrylate, 2-ethylhexyl acrylate, isoamyl acrylate, 2-(2-ethoxyethoxy)ethyl acrylate, phenoxyethyl acrylate, phenoxydiethyleneglycol acrylate, 2-{2-[(2-ethylhexyl)oxy]ethoxy}ethyl acrylate, 1,4-cyclohexanedimethanol monoacrylate, N,N-diethylacrylamide, N-(2-hydroxyethyl)acrylamide, and 4-acryloylmorpholine. However, this is merely an example, and the monomer having the polymerizable unsaturated group included in the resin composition RC should not be limited thereto or thereby. The monomer having the polymerizable unsaturated group in the resin composition RC may be a single type, or a combination of two or more types may be used.

In an embodiment, the urethane acrylate compound included in the resin composition RC may have a weight-average molecular weight of 5,000 or more to 10,000 or less. The weight-average molecular weight may be a value obtained by a gel permeation chromatography using a standard polystyrene conversion. The adhesive member AP (refer to FIG. 5) formed from the resin composition RC including the urethane acrylate compound that satisfies the above range may exhibit the above-mentioned 180° peel strength and yellowness index (YI) properties.

In an embodiment, the urethane acrylate compound included in the resin composition RC may have a number-average molecular weight of 2,000 or more to 8,000 or less. The number-average molecular weight may be obtained using an end-group analysis method such as a nuclear magnetic resonance (NMR) spectroscopy, but it should not be particularly limited as long as it is appropriately selected by one of ordinary skill in the art. The adhesive member AP (refer to FIG. 5) formed from the resin composition RC including the urethane acrylate compound that satisfies the above range may exhibit the above-mentioned 180° peel strength and yellowness index (YI) properties.

In an embodiment, the urethane acrylate compound included in the resin composition may be synthesized from reactants including the first polyfunctional alcohol including the structure of chemical formula 1, the second polyfunctional alcohol different from the first polyfunctional alcohol, the polyfunctional isocyanate-based compound, the compound including at least one (meth)acryloyl group and at least one hydroxyl group per molecule, and the mono-alcohol. However, the composition of the reactants should not be limited thereto or thereby, and other substances may be appropriately added as long as they do not significantly affect the final product. A catalyst or the like may be further added to the reactants when synthesizing the urethane acrylate compound.

In an embodiment, the content of the structure of chemical formula 1 in the urethane acrylate compound included in the resin composition may be 20 wt % or more to 60 wt % or less based on the total weight of the urethane acrylate compound. When the content of the structure of chemical formula 1 in the urethane acrylate compound satisfies the above range, the adhesive member formed from the resin composition including the urethane acrylate compound may exhibit high adhesiveness.

In an embodiment, the first polyfunctional alcohol including the structure of chemical formula 1 may include, for example, 2,2-bis(4-polyoxypropylene oxyphenyl)propane. However, this is merely an example, and the first polyfunctional alcohol including the structure of chemical formula 1 should not be limited thereto or thereby. The first polyfunctional alcohol including the structure of chemical formula 1 may be a single type, or a combination of two or more types may be used.

In an embodiment, the second polyfunctional alcohol may include at least one of 2,2-bis(hydroxymethyl)butyric acid, ethylene glycol, propylene glycol, butylene glycol, butylethylpropanediol, polyethylene glycol, and polypropylene glycol. However, this is merely an example, and the second polyfunctional alcohol should not be limited thereto or thereby. The second polyfunctional alcohol may be of a different type from the first polyfunctional alcohol including the structure of chemical formula 1. The second polyfunctional alcohol may be a single type, or a combination of two or more types may be used.

In an embodiment, the polyfunctional isocyanate-based compound may include at least one of 1,3-bis(isocyanatomethyl)cyclohexane and isophorone diisocyanate. However, this is merely an example, and the polyfunctional isocyanate-based compound should not be limited thereto or thereby. The polyfunctional isocyanate-based compound may be a single type, or a combination of two or more types may be used.

In an embodiment, the mono-alcohol may include an unsaturated mono-alcohol and a saturated mono-alcohol.

In an embodiment, the unsaturated mono-alcohol may include at least one of hydroxy dicyclopentadiene, 3-cyclohexene-1-methanol, and trans-2-hexen-1-ol. However, this is merely an example, and the unsaturated mono-alcohol should not be limited thereto or thereby. The unsaturated mono-alcohol may be a single type, or a combination of two or more types may be used. When the unsaturated mono-alcohol is not included in the reactant, the lightfastness may be reduced.

The saturated mono-alcohol may include at least one of methanol, ethanol, n-propanol, isopropanol, and n-butanol, but the saturated mono-alcohol of the present embodiment should not be limited thereto or thereby.

In an embodiment, the resin composition RC may include the photopolymerization initiator. The photopolymerization initiator may refer to a substance that absorbs light, such as ultraviolet light, to cause a polymerization reaction of monomers or oligomers.

For example, the photopolymerization initiator may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

In addition, the photopolymerization initiator may include at least one of 2-methyl-1-[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl)heptylideneamino]benzoate, [1-[9-ethyl-6-(2-methylbenzoyl)carbazol-3-yl]ethylideneamino]acetate, and bis(2,4-cyclopentadienyl)bis[2,6-difluoro-3-(1-pyrryl)phenyl]titanium IV.

In an embodiment, the resin composition may include bis(2,4,6-trimethylbenzoyl)phenyl phosphine oxide as the photopolymerization initiator. The photopolymerization initiator may be a single type, or a combination of two or more types may be used. However, the photopolymerization initiator is not limited to the types described above, and any suitable photopolymerization initiator that may be appropriately selected by a person skilled in the art may also be used.

Referring to FIG. 7B, the first light UV-1 may be provided to the resin composition RC coated on the substrate CF with a uniform thickness. The liquid resin composition RC may be cured by the first light UV-1 to form the preliminary adhesive member P-AP (refer to FIG. 7C). The first light UV-1 may be ultraviolet light. Although FIG. 7B illustrates the preliminary adhesive member P-AP being formed by directly irradiating the resin composition RC coated on the substrate CF with the first light UV-1, the present disclosure should not be limited thereto or thereby. A carrier film (not shown) may be disposed on the resin composition RC coated with the uniform thickness, and the carrier film (not shown) may transmit ultraviolet light.

Referring to FIGS. 7C and 7D, the preliminary adhesive member P-AP formed by irradiating the resin composition RC with the first light UV-1 (FIG. 7B) may be detached from the substrate CF and may be provided on one surface of the window WP or on one surface of the display module DM. One surface of the preliminary adhesive member P-AP may be attached to a surface of either the window WP or the display module DM, and the remaining one of the window WP or the display module DM, which is not attached to the preliminary adhesive member P-AP, may be attached to the other surface of the preliminary adhesive member P-AP. Then, the second light UV-2 may be irradiated onto the preliminary adhesive member P-AP to form the adhesive member AP (refer to FIGS. 4 and 5). The second light UV-2 may be ultraviolet light. The second light UV-2 may be provided from above the window WP, and the window WP may transmit the second light UV-2. The second light UV-2 may be provided to the preliminary adhesive member P-AP after passing through the window WP. In addition, the second light UV-2 may be provided to the preliminary adhesive member P-AP after passing through the printed layer BM.

An area of the preliminary adhesive member P-AP which overlaps with the printed layer BM may be irradiated with a smaller amount of the second light UV-2 than areas of the preliminary adhesive member P-AP which do not overlap with the printed layer BM.

Although FIGS. 7A to 7D illustrate the adhesive member AP (refer to FIGS. 4 and 5) being formed by curing the resin composition RC twice, that is, curing by providing light twice, the present disclosure should not be limited thereto or thereby. For example, the adhesive member AP may be formed by curing the resin composition RC once, or by curing the resin composition RC three or more times.

FIGS. 8A to 8C are views schematically illustrating a method of manufacturing the adhesive member AP from the resin composition RC according to an embodiment of the present disclosure. In the following descriptions with reference to FIGS. 8A to 8C, descriptions that are the same as those provided with reference to FIGS. 1 to 7D are omitted, and the description will focus on the differences.

The manufacturing method of the adhesive member AP shown in FIGS. 8A to 8C may include providing the resin composition RC on the display module DM, providing a first light UV-1 to the resin composition RC to form a preliminary adhesive member P-AP, and providing a second light UV-2 to the preliminary adhesive member P-AP to form the adhesive member AP. The manufacturing method shown in FIGS. 8A to 8C differs from the manufacturing method shown in FIGS. 7A to 7D in that the resin composition RC is provided on the display module DM.

The resin composition RC may be provided directly on one surface of the display module DM or on one surface of the window WP. FIG. 8A illustrates the resin composition RC being provided directly on the one surface of the display module DM.

Referring to FIG. 8B, the first light UV-1 may be provided to the resin composition RC that is uniformly coated. As the first light UV-1 is provided to the resin composition RC, the preliminary adhesive member P-AP may be formed. The window WP may be provided on the preliminary adhesive member P-AP. Referring to FIG. 8C, the second light UV-2 may be provided to the preliminary adhesive member P-AP after passing through the window WP. In addition, the second light UV-2 may be provided to the preliminary adhesive member P-AP after passing through the printed layer BM. The preliminary adhesive member P-AP may be cured by the second light UV-2, and thus, the adhesive member AP (refer to FIG. 5) may be formed.

The adhesive member AP (refer to FIG. 5) formed from the resin composition RC may have high adhesiveness and excellent lightfastness. In addition, the adhesive member AP (refer to FIG. 5) formed from the resin composition RC may also have high adhesiveness and excellent lightfastness even under the printed layer BM.

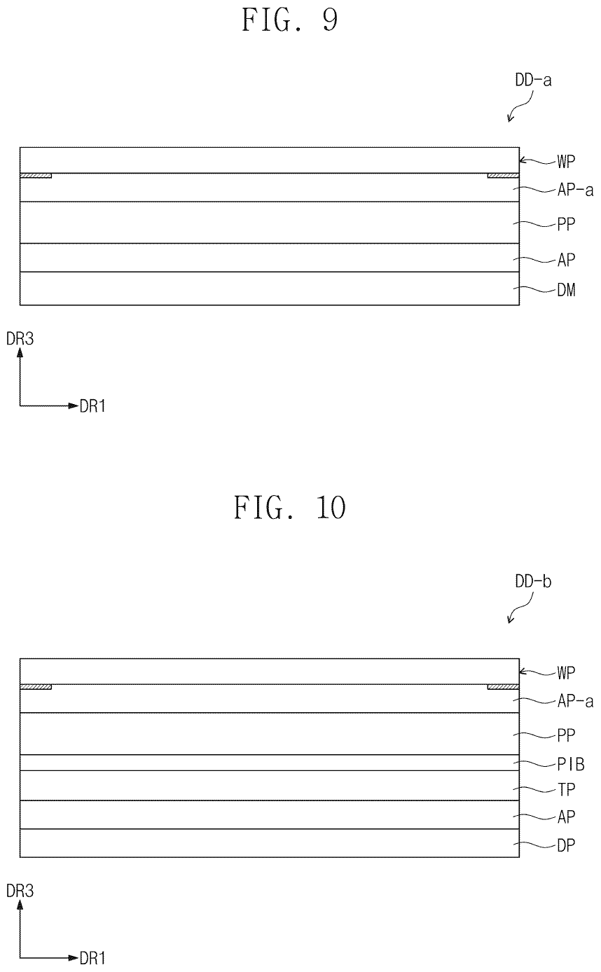

FIGS. 9 and 10 are cross-sectional views of display devices according to embodiments of the present disclosure. In the following descriptions of the display devices with reference to FIGS. 9 and 10, descriptions that are the same as those provided with reference to FIGS. 1 to 8C are omitted, and the description will focus on the differences.

Compared to the display device DD described with reference to FIGS. 4 and 5, the display device DD-a shown in FIG. 9 may further include a light control layer PP and an optical adhesive layer AP-a. The display device DD-a may further include the light control layer PP disposed between an adhesive member AP and a window WP and the optical adhesive layer AP-a disposed between the light control layer PP and the window WP. The light control layer PP may include a polarizer or a color filter layer.

The optical adhesive layer AP-a may be formed from a resin composition RC. The optical adhesive layer AP-a, which includes a polymer obtained from the resin composition RC, may have excellent adhesiveness and excellent lightfastness. The display device DD-a including the optical adhesive layer AP-a may exhibit excellent reliability and excellent display quality.

Compared to the display device DD described with reference to FIGS. 4 and 5, the display device DD-b shown in FIG. 10 may further include a light control layer PP, an optical adhesive layer AP-a, and an interlayer adhesive layer PIB.

In the display device DD-b, an adhesive member AP may be provided between a display panel DP and an input sensing unit TP. In other words, the input sensing unit TP may not be disposed directly on the display panel DP, but the display panel DP and the input sensing unit TP may be attached to each other by the adhesive member AP. For example, the adhesive member AP may be disposed between an encapsulation layer TFE (refer to FIG. 5) of the display panel DP and the input sensing unit TP.

The interlayer adhesive layer PIB may be provided under the light control layer PP. The interlayer adhesive layer PIB may be disposed between the input sensing unit TP and the light control layer PP and may be formed of an adhesive material with excellent moisture-proof properties. For example, the interlayer adhesive layer PIB may be formed including polyisobutylene. The interlayer adhesive layer PIB may be disposed on the input sensing unit TP and may prevent corrosion of sensing electrodes of the input sensing unit TP. The display device DD-b may include the optical adhesive layer AP-a and the adhesive member AP formed from a resin composition RC, and the display device DD-b including the optical adhesive layer AP-a and the adhesive member AP may exhibit excellent reliability and excellent display quality.

Hereinafter, the resin composition and the adhesive member formed from the resin composition according to the present disclosure will be described in detail with reference to embodiment examples and comparative examples. In addition, the embodiment examples provided below are merely to assist in the understanding of the present disclosure, and the scope of the present disclosure should not be limited thereto or thereby.

### Examples

Table 1 shows components and their content of resin compositions in embodiment examples and comparative examples. The resin compositions are prepared as liquid resin compositions by stirring the components of Table 1 below at room temperature. The content of each component in Table 1 is expressed in parts by weight.

In addition, Table 2 shows compounds used in the synthesis of urethane acrylates A-1 to A-8 provided in the resin compositions of embodiment examples and comparative examples and their content. In Table 2, the content is expressed in parts by weight. The synthesis methods for A-1 to A-8 are described in more detail below.

The resin compositions of embodiment example 1 to embodiment example 7 include the urethane acrylate compound including the structure of chemical formula 1 below, a monomer including one polymerizable unsaturated group per molecule, and a photopolymerization initiator. In the case of embodiment example 3, an ultraviolet light (UV) absorber is further included. The content of the monomer in the resin compositions of embodiment example 1 to embodiment example 7 is in a range of 50 wt % to 95 wt % based on the total weight of the resin composition.

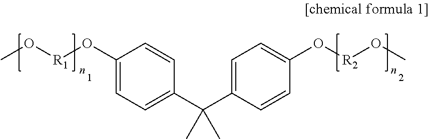

In the embodiment examples, A-1 to A-5 are used in the resin composition as the urethane acrylate compounds including the structure of chemical formula 1.

In the embodiment examples, 4-HBA, THF-A, IBXA, and IDAA are used as the monomer including one polymerizable unsaturated group per molecule. In the embodiment examples, Omnirad 819 is used as the photopolymerization initiator. In the case of embodiment example 3, Tinuvin 329 is used as the UV absorber.

The urethane acrylate compounds used in the resin compositions of embodiment examples 1 to 7 correspond to compounds synthesized from reactants including a first polyfunctional alcohol including the structure of chemical formula 1, a second polyfunctional alcohol different from the first polyfunctional alcohol, a polyfunctional isocyanate-based compound, a compound including at least one (meth)acryloyl group and at least one hydroxyl group per molecule, and a mono-alcohol. A catalyst is used together during the synthesis of the urethane acrylate compounds.

In this case, 2,2-bis(4-polyoxypropylene oxyphenyl)propane is used as the first polyfunctional alcohol including the structure of chemical formula 1. In addition, 2,2-bis(hydroxymethyl)butyric acid is used as the second polyfunctional alcohol, and PLACCEL FA1DDM is used as the compound including at least one (meth)acryloyl group and at least one hydroxyl group per molecule. As the mono-alcohol, hydroxy dicyclopentadiene, 3-cyclohexene-1-methanol, trans-2-hexen-1-ol, and ethanol are used.

In the urethane acrylate compounds in the resin compositions of embodiment examples 1 to 7, the content of the structure of chemical formula 1 is in a range of 20 wt % or more to 60 wt % or less based on the total weight of the urethane acrylate compound.

Embodiment example 1 and embodiment example 2 have the same components in their resin compositions, but they differ in the content of the urethane acrylate used.

Embodiment example 3 uses the same components in the same amounts as embodiment example 1 but differs in that embodiment example 3 additionally includes the UV absorber.

Embodiment examples 4 to 7 use a different type of urethane acrylate from embodiment example 1, and the remaining components and their content are the same.

On the other hand, in the case of comparative example 1, A-8 is used as the urethane acrylate. That is, the unsaturated mono-alcohol is not included in the reactants during the synthesis of the urethane acrylate. Further, in the case of comparative example 2, the UV absorber is added to comparative example 1.

In comparative example 3 and comparative example 4, the urethane acrylate used is different from that used in the embodiment examples. In comparative example 3, the content of the structure of chemical formula 1 exceeds 60 wt % of the total weight of the urethane acrylate. In addition, in comparative example 4, the content of the structure of chemical formula 1 is less than 20 wt % of the total weight of the urethane acrylate.

In comparative example 5, the urethane acrylate that does not include the structure of chemical formula 1 is used, unlike in the embodiment examples.

TABLE 1

| | | Embodiment example | | | | | | | Comparative example | | | | |
|---|---|---|---|---|---|---|---|---|---|---|---|---|---|
| Component | Compound | 1 | 2 | 3 | 4 | 5 | 6 | 7 | 1 | 2 | 3 | 4 | 5 |
| Urethane | A-1 | 1.7 | 2 | 1.7 | | | | | | | | | |
| acrylate | A-2 | | | | 1.7 | | | | | | | | |
| | A-3 | | | | | 1.7 | | | | | | | |
| | A-4 | | | | | | 1.7 | | | | | | |
| | A-5 | | | | | | | 1.7 | | | | | |
| | A-6 | | | | | | | | | | 1.7 | | |
| | A-7 | | | | | | | | | | | 1.7 | |
| | A-8 | | | | | | | | 1.7 | 1.7 | | | |
| | UV3300 | | | | | | | | | | | | 1.7 |
| Monomer | 4 -HBA | 1.5 | 1.5 | 1.5 | 1.5 | 1.5 | 1.5 | 1.5 | 1.5 | 1.5 | 1.5 | 1.5 | 1.5 |
| having one | THF-A | 5.0 | 5.0 | 5.0 | 5.0 | 5.0 | 5.0 | 5.0 | 5.0 | 5.0 | 5.0 | 5.0 | 5.0 |
| polymerizable | IBXA | 1.5 | 1.5 | 1.5 | 1.5 | 1.5 | 1.5 | 1.5 | 1.5 | 1.5 | 1.5 | 1.5 | 1.5 |
| unsaturated | IDAA | 2.0 | 2.0 | 2.0 | 2.0 | 2.0 | 2.0 | 2.0 | 2.0 | 2.0 | 2.0 | 2.0 | 2.0 |
| group per | | | | | | | | | | | | | |
| molecule | | | | | | | | | | | | | |
| UV | Tinuvin | | | 0.01 | | | | | | 0.01 | | | |
| absorber | 329 | | | | | | | | | | | | |
| photopoly- | Omnirad | 0.13 | 0.13 | 0.13 | 0.13 | 0.13 | 0.13 | 0.13 | 0.13 | 0.13 | 0.13 | 0.13 | 0.13 |
| merization | 819 | | | | | | | | | | | | |
| initiator | | | | | | | | | | | | | |

The compounds used in Table 1 are as follows. 4-HBA: 4-hydroxybutyl acrylate (product of Osaka Organic Chemical Industry Ltd.)
THF-A: Tetrahydrofurfuryl acrylate (product of Kyoeisha Chemical Co., Ltd.)
IBXA: Isobornyl acrylate (product of Osaka Organic Chemical Industry Ltd.)
IDAA: Isodecyl acrylate (product of Osaka Organic Chemical Industry Ltd.)
UV3300B: Urethane acrylate (molecular weight 13000) (product of Mitsubishi Chemical Corporation)
Omnirad 819: Bis(2,4,6-trimethylbenzoyl)phenylphosphine oxide (product of IGM Resins)
Tinuvin 329: 2Phenol, 2-(2H-benzotriazol-2-yl)-4-(1,1,3,3-tetramethylbutyl) (product of BASF)

Furthermore, the urethane acrylates A-1 to A-8 used in Table 1 are also prepared using the compounds from Table 2 below.

### Synthesis Method of A-1

To a flask equipped with a stirring rod, a temperature sensor, and a water-cooled condenser, 38.5 parts by weight of BA-P8, 8.5 parts by weight of 2,2-bis(hydroxymethyl)butyric acid, and 7.6 parts by weight of PLACCEL FA1DDM were added. Then, 0.01 parts by weight of dibutyltin dilaurate was added, and the mixture was stirred using the stirring rod and heated to 60° C. After that, 32 parts by weight of 1,3-bis(isocyanatomethyl)cyclohexane was added to prepare a mixture while paying attention to exothermic heat. The temperature of the mixture was raised to 85° C. and maintained for 2 hours.

When the content of isocyanate in the total weight of the mixture was 3 wt % or less, the temperature was lowered to 70° C. Subsequently, 5.0 parts by weight of hydroxy dicyclopentadiene and 1.5 parts by weight of ethanol were added, and the temperature was raised to 80° C. The mixture was reacted until the isocyanate content became 0.1 wt % and then cooled to obtain the urethane acrylate A-1. In this case, the isocyanate content represents the amount of isocyanate groups present in a sample as a mass fraction. It was calculated by reacting a collected sample with a dibutylamine solution and measuring a titrated amount in a standard hydrochloric acid solution.

A-2 to A-8 were also prepared in the same manner, but with different components and contents according to Table 2.

A-1 to A-5 may correspond to compounds synthesized from reactants including the polyfunctional alcohol having the structure of chemical formula 1, the polyfunctional saturated alcohol different from the polyfunctional alcohol, the polyfunctional isocyanate-based compound, the compound including at least one (meth)acryloyl group and at least one hydroxyl group per molecule, and the unsaturated mono-alcohol.

In addition, a weight-average molecular weight (Mw) of the synthesized urethane acrylates A-1 to A-5 is in a range of 5,000 or more to 10,000 or less, and a number-average molecular weight (Mn) is in a range of 2,000 or more to 8,000 or less.

In the urethane acrylate compounds of A-1 to A-5 synthesized by the method described above, the content of the structure of chemical formula 1 is in a range of 20 wt % or more to 60 wt % or less based on the total weight of the urethane acrylate compound.

On the other hand, in the urethane acrylate compound of A-6, the content of the structure of chemical formula 1 exceeds 60 wt % of the total weight of the urethane acrylate compound. In addition, in the urethane acrylate compound of A-7, the content of the structure of chemical formula 1 is less than 20 wt % the total weight of the urethane acrylate compound.

The urethane acrylate compound of A-8 is different in that the urethane acrylate compound of A-8 does not include the unsaturated mono-alcohol in the reactant.

TABLE 2

| | | | Synthesis | Synthesis | Synthesis | Synthesis | Synthesis | Synthesis | Synthesis | Synthesis |
|---|---|---|---|---|---|---|---|---|---|---|
| | | | example | example | example | example | example | example | example | example |
| | | | 1 | 2 | 3 | 4 | 5 | 6 | 7 | 8 |
| urethane acrylate | | | A-1 | A-2 | A-3 | A-4 | A-5 | A-6 | A-7 | A-8 |
| first | | BA-P8 | 38.5 | 38.5 | 38.5 | | 76.8 | 81.8 | 10.9 | 38.3 |
| polyfunctional | | BA-P3U | | | | 16.5 | | | | |
| alcohol (including | | | | | | | | | | |
| chemical formula | | | | | | | | | | |
| 1) | | | | | | | | | | |
| second | | 2,2- | 8.5 | 8.5 | 8.5 | 11 | 5 | 1.2 | 13.4 | 8.6 |
| polyfunctional | | bis(hydroxymethyl)butyric | | | | | | | | |
| alcohol (not | | acid | | | | | | | | |
| including | | | | | | | | | | |
| chemical formula | | | | | | | | | | |
| 1) | | | | | | | | | | |
| polyfunctional | | 1,3-bis (isocyanato | 32.0 | 32.0 | 32.0 | | | | | 32.0 |
| isocyanate-based | | methyl) cyclohexane | | | | | | | | |
| compound | | isophorone | | | | 37.0 | 36.7 | 36.7 | 36.7 | |
| | | diisocyanate | | | | | | | | |
| Compound | | PLACCEL | 7.6 | 7.6 | 7.6 | 7.6 | 7.6 | 3.8 | 15.1 | 7.6 |
| containing at least | | FA1DDM | | | | | | | | |
| one | | | | | | | | | | |
| (meth)acryloyl | | | | | | | | | | |
| group and at least | | | | | | | | | | |
| one hydroxyl | | | | | | | | | | |
| group per | | | | | | | | | | |
| molecule | | | | | | | | | | |
| mono- | Unsaturated | hydroxydicyclo- | 5.0 | | | 5.0 | 5.0 | 5.0 | 5.0 | |
| alcohol | alcohol | pentadiene | | | | | | | | |
| | | 3-cyclohexene-1- | | 3.7 | | | | | | |
| | | methanol | | | | | | | | |
| | | trans-2-hexen-1-ol | | | 3.3 | | | | | |
| | Saturated | Ethanol | 1.5 | 1.5 | 1.5 | 1.5 | 0.8 | 0.8 | 1.5 | 3.1 |
| | alcohol | | 0.01 | 0.01 | 0.01 | 0.01 | 0.01 | 0.01 | 0.01 | 0.01 |

| | | | | | | | | |
|---|---|---|---|---|---|---|---|---|
| Dibutyltin dilaurate (catalyst) | 7820 | 7800 | 8100 | 6800 | 9200 | 11000 | 4800 | 7800 |
| Molecular weight (Mw) | 4510 | 5800 | 4600 | 3870 | 5100 | 5650 | 2800 | 5800 |
| Molecular weight (Mn) | 41 | 42 | 42 | 21 | 58 | 63 | 13 | 43 |
| Weight % of structure of chemical formula 1 | | | | | | | | |

The compounds used in Table 2 are as follows. The content of each component in Table 2 is expressed in parts by weight. In addition, the weight percentage (wt %) of the structure of chemical formula 1 in Table 2 is based on the total weight of the urethane acrylate.
BA-P8: 2,2-bis(4-polyoxypropylene oxyphenyl)propane (Product of Nippon Nyukazai Co., Ltd.)
BA-P3U: 2,2-bis(4-polyoxypropylene oxyphenyl)propane (Product of Nippon Nyukazai Co., Ltd.)
1,3-bis(isocyanatomethyl)cyclohexane: (Product of Mitsubishi Chemical Corporation)
Dibutyltin Dilaurate: (Product of TCI)
Hydroxy dicyclopentadiene: (Product of TCI)
PLACCEL FA1DDM: Caprolactone-modified acrylate (Product of Daicel Corporation)
3-cyclohexene-1-methanol: (Product of TCI)
trans-2-hexen-1-ol: (Product of TCI)

In Table 3 below, the physical properties of the adhesive members formed by curing the resin compositions are evaluated and shown. The evaluation methods for each characteristic are as follows.

### <Viscosity Measurement>

The viscosity of the liquid resin compositions of embodiment examples or comparative examples was measured at 25° C. in accordance with JIS K 2283.

### <Measurement of Yellowness Index (YI) of Adhesive Member>

The liquid resin compositions of embodiment examples and comparative examples were provided between slide glasses (S 112, Matsunami Glass), to which a spacer with a thickness of 200 μm was attached. The resin composition applied between the slide glasses was irradiated twice with ultraviolet (UV) light using a UV-LED lamp with peak wavelengths at 365 nm and 385 nm, so that cumulative UV doses became 500 mJ/cm² and 260 mJ/cm², respectively, to obtain a sample in which the resin composition was cured.

The yellowness index of the obtained sample was measured. The yellowness index was measured at different points to obtain an initial value, which is measured immediately after curing, and a value measured after a 48-hour lightfastness test. In this case, the yellowness index (YI) was measured using a spectrophotometer (COH 7700) from Nippon Denshoku Industries Co., Ltd.

In the initial value of the yellowness index, the degree of coloration is verified based on the YI value. For the lightfastness test, the sample used to measure the initial value of the yellowness index was exposed to a Q-SUN Xenon Test Chamber from Q-Lab Corporation for 48 hours under conditions of 0.4 W/50° C., and then, the sample was retrieved to measure the YI value. The Q-SUN Xenon Test Chamber from Q-Lab Corporation uses a xenon arc lamp.

The results of the YI value measurement are shown in Table 3 according to the following criteria based on the numerical ranges.
⊚: YI≤0.5
∘: 0.5≤YI<1.0
X: YI≥1.0

### <Measurement of 180° Peel Strength of Adhesive Member>

The resin composition was coated on a soda-lime glass with a size of 26 mm×76 mm (Central Glass Co., Ltd.) using an inkjet device to have a thickness of 150 μm. The resin composition was irradiated twice with ultraviolet (UV) light using a UV-LED lamp having peaks at 365 nm and 385 nm, with cumulative UV doses of 500 mJ/cm² and 260 mJ/cm², respectively. A PET film with a size of 20 mm×150 mm (Toyobo Co., Ltd., A4360: 50 μm) was laminated onto the UV-irradiated soda-lime glass at a lamination pressure of 0.15 MPa to obtain a sample. The peel strength of the sample was measured using a universal testing machine (Instron Model 5965) at 25° C. at a peel speed of 300 mm/min and a peel angle of 180°. The peel strength was measured three times, and after calculating the average value of about 50 mm of peel, the obtained value was then multiplied by 1.25 for evaluation.

TABLE 3

| | | Em- | Em- | Em- | Em- | Em- | Em- | Em- | Com- | Com- | Com- | Com- | Com- |
|---|---|---|---|---|---|---|---|---|---|---|---|---|---|
| | | bodi- | bodi- | bodi- | bodi- | bodi- | bodi- | bodi- | par- | par- | par- | par- | par- |
| | | ment | ment | ment | ment | ment | ment | ment | ative | ative | ative | ative | ative |
| | | exam- | exam- | exam- | exam- | exam- | exam- | exam- | exam- | exam- | exam- | exam- | exam- |
| | | ple 1 | ple 2 | ple 3 | ple 4 | ple 5 | ple 6 | ple 7 | ple 1 | ple 2 | ple 3 | ple 4 | ple 5 |
| Viscosity (25° C.) | | 12.3 | 15.4 | 12.4 | 12.2 | 12.3 | 11.9 | 14.1 | 12.2 | 12.4 | 15.3 | 12.1 | 11.6 |
| (mPa · s) | | | | | | | | | | | | | |
| YI | Right | ◯ | ◯ | ◯ | ◯ | ◯ | ◯ | ◯ | ◯ | X | ◯ | ◯ | ◯ |
| | after | | | | | | | | | | | | |
| | curing | | | | | | | | | | | | |
| | After | ◯ | ⊚ | ⊚ | ⊚ | ◯ | ◯ | ◯ | X | ⊚ | ◯ | ◯ | X |
| | 48 | | | | | | | | | | | | |
| | hours | | | | | | | | | | | | |

| | | | | | | | | | | | | |
|---|---|---|---|---|---|---|---|---|---|---|---|---|
| 180° peel strength | 4000 | 4000 | 3600 | 3800 | 3700 | 3100 | 3800 | 4300 | 4200 | 1200 | 800 | 10 |
| gf/25 mm | | | | | | | | | | | | |

Referring to Table 3, it is observed that the adhesive member of comparative example 1 has the yellowness index (YI) value of 1.0 or more after 48 hours in the lightfastness test. This indicates that the adhesive member of comparative example 1 has lower lightfastness compared to the embodiment examples. In the resin composition of comparative example 1, the unsaturated mono-alcohol was not included in the reactants during the synthesis of the urethane acrylate. In addition, in the case of the resin composition of comparative example 2, the UV absorber was added to the resin composition of comparative example 1, and coloration of the adhesive member was observed right after curing.

In the resin compositions of comparative examples 3 and 4, the content of the structure of chemical formula 1 in the urethane acrylate compound is less than 20 wt % or more than 60 wt % based on the total weight of the urethane acrylate compound. It is observed that the adhesive members formed from the resin compositions have low 180° peel strength and low lightfastness.

In the case of the adhesive member of comparative example 5 in which the urethane acrylate not containing the structure of chemical formula 1 was used, it is observed that the 180° peel strength is remarkably lower.

In contrast, it is observed that the adhesive members obtained by photocuring the resin compositions of embodiment examples 1 to 7 have the 180° peel strength of 2000 gf/25 mm or more at 25° C. and excellent lightfastness.

In addition, it is observed that the resin compositions of embodiment examples 1 to 7 have a low viscosity, with a measured viscosity of 20 mPa s or less at 25° C.

The resin composition of the present disclosure may have low viscosity and may exhibit high adhesive properties and excellent lightfastness after curing.

The adhesive member of the present disclosure may have high adhesive properties and excellent lightfastness.

The electronic apparatus including the polymer obtained from the resin composition according to the present disclosure may have excellent reliability and excellent display quality.

Although the embodiments of the present disclosure have been described, it is understood that the present disclosure should not be limited to these embodiments, but various changes and modifications can be made by one ordinary skilled in the art within the spirit and scope of the present disclosure as hereinafter claimed.

Therefore, the disclosed subject matter should not be limited to any single embodiment described herein, and the scope of the present disclosure shall be determined according to the attached claims.

What is claimed is:

1. A resin composition comprising:
a urethane acrylate compound comprising a structure of chemical formula 1 below;
a monomer comprising one polymerizable unsaturated group per molecule; and
a photopolymerization initiator,
wherein the urethane acrylate compound is synthesized from reactants comprising:
a first polyfunctional alcohol comprising the structure of chemical formula 1 below;
a second polyfunctional alcohol different from the first polyfunctional alcohol;
a polyfunctional isocyanate-based compound;
a compound comprising at least one (meth)acryloyl group and at least one hydroxyl group per molecule; and
a mono-alcohol,
wherein a content of the structure of chemical formula 1 in the urethane acrylate compound is 20 wt % or more and 60 wt % or less based on a total weight of the urethane acrylate compound, and
wherein a content of the monomer is 50 wt % or more and 95 wt % or less based on a total weight of the resin composition, 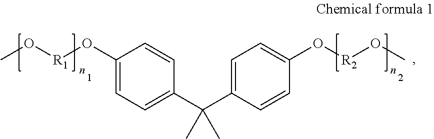
in chemical formula 1, each of R₁ and R₂ is independently a substituted or unsubstituted alkylene group having 1 or more to 4 or less carbon atoms, and each of n₁ and n₂ is independently an integer of 1 or more and 6 or less.

2. The resin composition of claim 1, wherein a 180° peel strength with respect to a glass substrate, measured at 25° C. after photocuring under a condition where a cumulative UV dose is less than 2000 mJ/cm² under atmospheric conditions, is 2000 gf/25 mm or more to 5000 gf/25 mm or less.

3. The resin composition of claim 1, wherein the polymerizable unsaturated group in the monomer is an acrylate group.

4. The resin composition of claim 1, wherein the monomer comprises at least one of 4-hydroxybutyl acrylate, tetrahydrofurfuryl acrylate, isobornyl acrylate, isodecyl acrylate, lauryl acrylate, 2-ethylhexyl acrylate, and 2-{2-[(2-ethylhexyl)oxy]ethoxy}ethyl acrylate.

5. The resin composition of claim 1, wherein the urethane acrylate compound has a weight-average molecular weight of 5,000 or more to 10,000 or less, and the urethane acrylate compound has a number-average molecular weight of 2,000 or more to 8,000 or less.

6. The resin composition of claim 1, wherein a yellowness index right after photocuring or a yellowness index after a 48-hour exposure to a xenon arc lamp under a condition of 0.4 W/50° C. is 1 or less.

7. The resin composition of claim 1, wherein the second polyfunctional alcohol comprises at least one of 2,2-bis(hydroxymethyl)butyric acid, ethylene glycol, propylene glycol, butylene glycol, butylethylpropanediol, polyethylene glycol, and polypropylene glycol.

8. The resin composition of claim 1, wherein the polyfunctional isocyanate-based compound comprises at least one of 1,3-bis(isocyanatomethyl)cyclohexane and isophorone diisocyanate.

9. The resin composition of claim 1, wherein the mono-alcohol comprises an unsaturated mono-alcohol and a saturated mono-alcohol, the unsaturated mono-alcohol comprises at least one of hydroxy dicyclopentadiene, 3-cyclohexene-1-methanol, and trans-2-hexen-1-ol, and the saturated mono-alcohol comprises at least one of methanol, ethanol, n-propanol, isopropanol, and n-butanol.

10. The resin composition of claim 1, wherein the photopolymerization initiator comprises bis(2,4,6-trimethylbenzoyl)phenyl phosphine oxide.

11. The resin composition of claim 1, further comprising an ultraviolet light (UV) absorber.

12. A urethane acrylate compound comprising a structure of chemical formula 1 below;
wherein the urethane acrylate compound is synthesized from reactants comprising:
a first polyfunctional alcohol comprising the structure of chemical formula 1 below, wherein the first polyfunctional alcohol comprises 2,2-bis(4-polyoxypropylene oxyphenyl)propane;
a second polyfunctional alcohol different from the first polyfunctional alcohol, wherein the second polyfunctional alcohol comprises at least one of 2,2-bis(hydroxymethyl)butyric acid, ethylene glycol, propylene glycol, butylene glycol, butylethylpropanediol, polyethylene glycol, and polypropylene glycol;
a polyfunctional isocyanate-based compound, wherein the polyfunctional isocyanate-based compound comprises at least one of 1,3-bis(isocyanatomethyl)cyclohexane and isophorone diisocyanate;
a compound comprising at least one (meth)acryloyl group and at least one hydroxyl group per molecule; and
a mono-alcohol, wherein the mono-alcohol comprises an unsaturated mono-alcohol and a saturated mono-alcohol, the unsaturated mono-alcohol comprises at least one of hydroxy dicyclopentadiene, 3-cyclohexene-1-methanol, and trans-2-hexen-1-ol, and the saturated mono-alcohol comprises at least one of methanol, ethanol, n-propanol, isopropanol, and n-butanol,
wherein a content of the structure of chemical formula 1 in the urethane acrylate compound is 20 wt % or more and 60 wt % or less based on a total weight of the urethane acrylate compound, 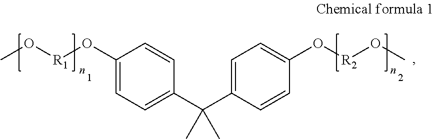
in chemical formula 1, each of R₁ and R₂ is independently a substituted or unsubstituted alkylene group having 1 or more to 4 or less carbon atoms, and each of n₁ and n₂ is independently an integer of 1 or more and 6 or less.

13. An adhesive member comprising:
a polymer obtained from a resin composition, the resin composition comprising:
a urethane acrylate compound comprising a structure of chemical formula 1 below;
a monomer comprising one polymerizable unsaturated group per molecule; and
a photopolymerization initiator,
wherein the urethane acrylate compound is synthesized from reactants comprising:
a first polyfunctional alcohol comprising the structure of chemical formula 1 below;
a second polyfunctional alcohol different from the first polyfunctional alcohol;
a polyfunctional isocyanate-based compound;
a compound comprising at least one (meth)acryloyl group and at least one hydroxyl group per molecule; and
a mono-alcohol,
wherein a content of the structure of chemical formula 1 in the urethane acrylate compound is 20 wt % or more and 60 wt % or less based on a total weight of the urethane acrylate compound, and
wherein a content of the monomer is 50 wt % or more and 95 wt % or less based on a total weight of the resin composition, 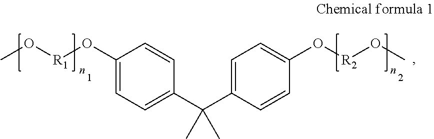
in chemical formula 1, each of R₁ and R₂ is independently a substituted or unsubstituted alkylene group having 1 or more to 4 or less carbon atoms, and each of n₁ and n₂ is independently an integer of 1 or more and 6 or less.

14. The adhesive member of claim 13, wherein a 180° peel strength with respect to a glass substrate measured at 25° C. is in a range of 2000 gf/25 mm or more to 5000 gf/25 mm or less.

15. The adhesive member of claim 13, wherein a thickness of the adhesive member is in a range of 50 μm or more and 300 μm or less.

16. An electronic apparatus comprising:
a display device providing an image, the display device comprising at least one adhesive member comprising a polymer obtained from the resin composition of claim 1.

17. The electronic apparatus of claim 16, wherein a 180° peel strength of the at least one adhesive member with respect to a glass substrate, which is measured at 25° C., is in a range of 2000 gf/25 mm or more to 5000 gf/25 mm or less.

18. The electronic apparatus of claim 16, wherein the display device comprises a display module and a window, and an adhesive member of the at least one adhesive member is between the display module and the window.

19. The electronic apparatus of claim 18, wherein the window comprises a base layer and a printed layer between the adhesive member and the base layer, and the adhesive member is formed by irradiating the resin composition on one surface of the display module or on one surface of the window with light through the printed layer.

20. The electronic apparatus of claim 16, wherein the display device comprises a display module, a processor, a memory, and a power module.
